(19) United States
(12) Patent Application Publication
(10) Pub. No.: US 2009/0189597 A1
(43) Pub. Date: Jul. 30, 2009

(54) INSTRUMENT FOR TESTING AN ELECTRICAL CIRCUIT

(75) Inventors: Chris Lagerberg, Seattle, WA (US); Duncan Kearsley, Stanwood, WA (US); Matthew Castle, Lynnwood, WA (US); Charles Bowden, Seattle, WA (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: FLUKE CORPORATION, Everett, WA (US)

(21) Appl. No.: 12/022,793

(22) Filed: Jan. 30, 2008

(51) Int. Cl. G01R 19/155

(52) U.S. Cl. 324/133

(57) ABSTRACT

An instrument for testing an electrical circuit includes a housing, a printed circuit board disposed within the housing, and at least one probe in electrical communication with the printed circuit board. The instrument further includes a plurality of panels disposed within the housing, wherein each one of the plurality of panels has an indicator. Each of the plurality of panels is capable of being activated into an on state in response to an electrical measurement. When at least one of the plurality of panels is activated the indicator on that panel substantially corresponds to a magnitude of the electrical measurement.

### BACKGROUND

Test instruments, such as digital multimeters, ohmmeters, amp meters, etc., are used in both commercial and residential applications to measure the properties of an electrical circuit. Electrical voltage testers are well known tools for measuring the voltage across two points. For instance, electrical voltage testers are commonly used to test a wall outlet to determine the voltage existing across the two main nodes of the outlet. The tester may also be used to determine voltages between a wire thought to be hot and ground or any other two points between which a voltage is suspected.

A typical test instrument such as an electrical voltage tester includes at least one indicator for representing the voltage between the two points being measured. The tester may include a digital or analog display that indicates the voltage level between the two points, e.g., 120 volts (120V). A display is very useful for indicating a substantially precise measurement of the voltage; however, the display is often difficult or impossible to see in low lighting situations. Accordingly, the tester may additionally include an audible alarm to indicate that a voltage is present. In extremely noisy situations, the tester may additionally vibrate or provide another tactile notification to indicate that a voltage is present. Although the audio and tactile alarms are useful for indicating voltage in low lighting situations, they do not provide the advantage of indicating the measured voltage level.

Some electrical voltage testers include a voltage scale comprising a plurality of ascending voltage numbers printed on the exterior of the tester housing and a plurality of light emitting diodes (LEDs) projecting through the housing adjacent to the voltage scale. The LEDS may light up adjacent to the voltage scale numbers to indicate the level of voltage being measured. As such, the number of LEDs illuminated approximately corresponds to the level of voltage being measured. The LEDs provide a supplemental indication of voltage levels when the tester is being used in low lighting situations.

Although the number of illuminated LEDs corresponds to the level of voltage being measured, the voltage scale is still difficult or impossible to see in a low lighting situation. Thus, the user would need to remember, for example that 3 illuminated LEDs represents 120V, 6 LEDs represents 240V, etc. This is not only a cumbersome method of measuring the voltage, but it is also prone to human error in reading the measurement.

Thus, it is desired to have an improved instrument for testing an electrical circuit that is capable of providing precise measurements in low lighting situations.

### SUMMARY

An instrument for testing an electrical circuit includes a housing, a printed circuit board disposed within the housing, and at least one probe in electrical communication with the printed circuit board. The instrument further includes a plurality of panels disposed within the housing, wherein each one of the plurality of panels has an indicator. Each of the plurality of panels is capable of being activated into an on state in response to an electrical measurement. When at least one of the plurality of panels is activated the indicator on that panel substantially corresponds to a magnitude of the electrical measurement.

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

### DESCRIPTION OF THE DRAWINGS

The foregoing aspects and many of the attendant advantages of the present disclosure will be better understood by reference to the following detailed description, when taken in conjunction with the accompanying drawings, wherein:

FIG. 1 is an isometric view of an instrument for testing an electrical circuit formed in accordance with one embodiment of the present disclosure;

FIG. 2 is an exploded view of the instrument of FIG. 1; and

FIG. 3 is a front plan view of the instrument of FIG. 1.

### DETAILED DESCRIPTION

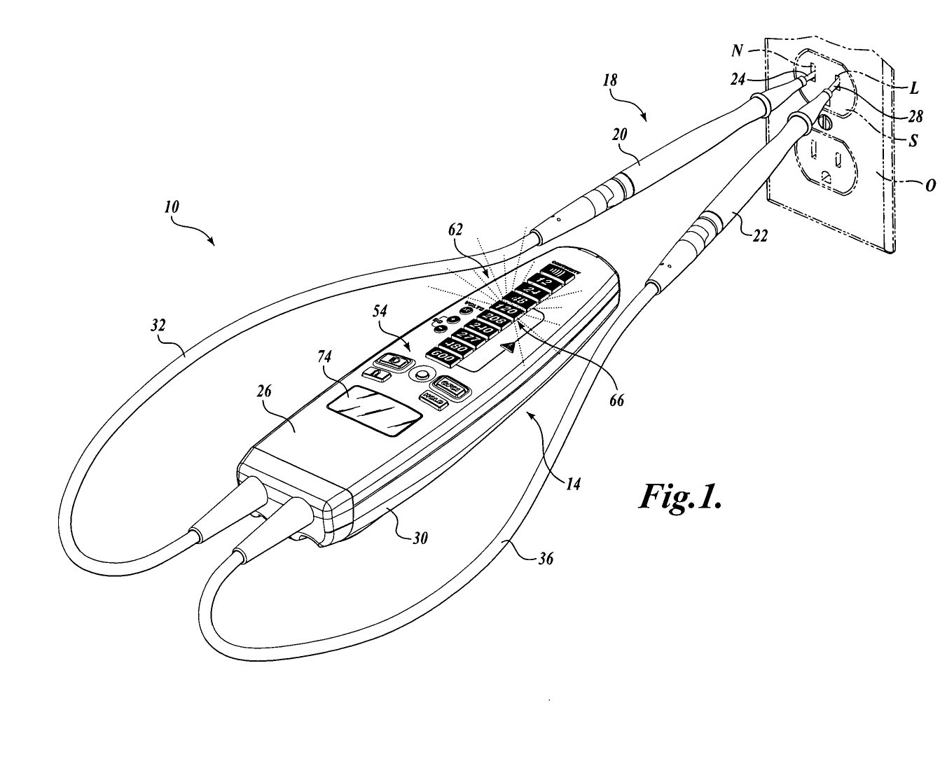

An instrument for testing an electrical circuit constructed in accordance with one embodiment of the present disclosure can best be seen by referring to FIG. 1. The instrument for testing an electrical circuit is embodied as a voltmeter 10; however, it should be appreciated that aspects of the voltmeter 10 hereinafter described may be suitable for use with other instruments, such as digital multimeters, clamp meters, ohmmeters, amp meters, etc. Thus, the description hereinafter provided should not be seen as limiting the scope of the claimed subject matter.

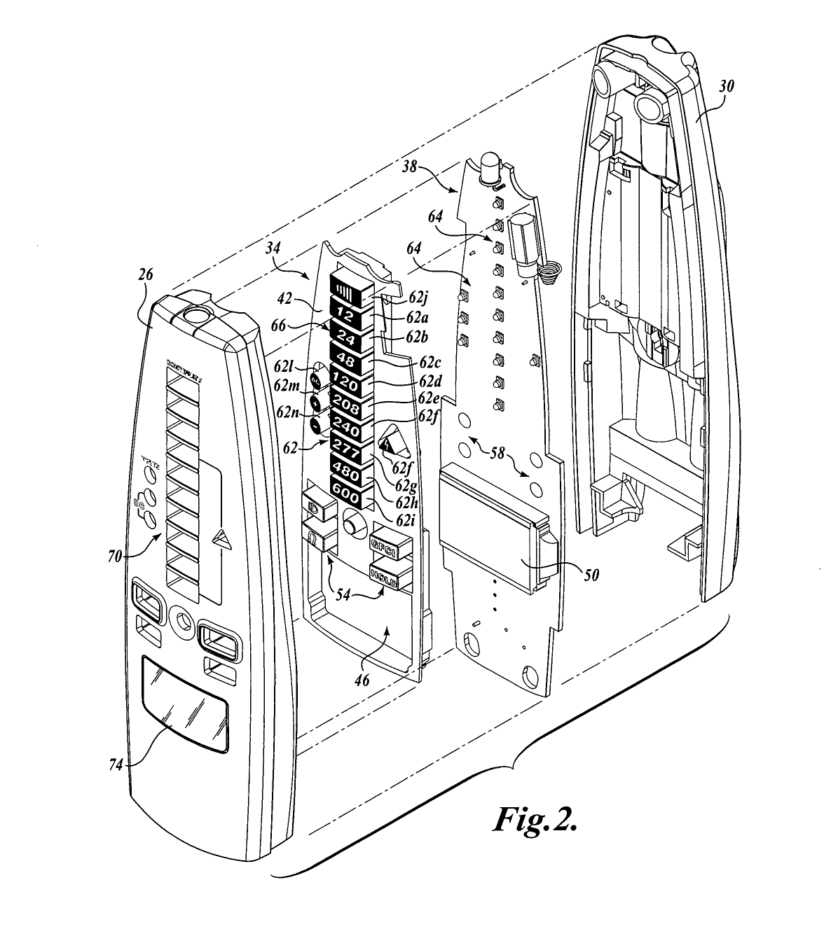

Referring to FIG. 1, the voltmeter 10 includes a housing 14 and a probe assembly 18 extending from the housing 14. The probe assembly 18 is constructed in any suitable, well known manner, and preferably includes first and second probes 20 and 22 having first and second conductive tips 24 and 28. The conductive tips 24 and 28 are used to test an electrical circuit by holding the tips 24 and 28 against a conductive element or area in which the voltage, continuity, or other electrical property is to be tested and/or measured. The first and second conductive tips 24 and 28 are electrically connected to first and second leads 32 and 36 of any suitable length that extend toward the housing 14. The first and second leads 32 and 36 are electrically connected to suitable testing and measurement circuitry of a printed circuit board (PCB) 38 enclosed within the housing 14 (see FIG. 2).

Referring to FIGS. 1 and 2, the housing 14 is made of a durable lightweight material, such as plastic, and is adapted to enclose internal electrical and mechanical components of the voltmeter 10. The housing 14 is any suitable shape and preferably includes a front housing portion 26 engaged with a rear housing portion 30 in a well known manner. The front and rear housing portions 26 and 30 enclose an indicator assembly 34, the PCB 38, and any other necessary components, such as a battery, flash light bulb, etc.

The indicator assembly 34 includes a rigid base 42 having a plurality of pushbuttons 54 or other input or output devices formed or received within the base 42. The pushbuttons 54 are adapted to be placed into electrical communication with a plurality of electrical contacts 58 on the PCB 38. Preferably, the pushbuttons 54 are used to select different testing, measurement, and indicator functions and modes of the voltmeter 10 or are used to turn on and off certain features of the voltmeter 10. For instance, the pushbuttons 54 can be used to select a ground fault circuit interrupter (GFCI) mode or an ohmmeter mode, or they can be used to turn a continuity beeper on or off, or to turn a flashlight on or off. The PCB 38 includes suitable circuitry for receiving the inputs of the pushbuttons 54 and changing the testing or measurement mode of the voltmeter 10 or turning the tester features on or off.

The base 42 further includes a bottom opening 46 positioned below the pushbuttons 54 and adapted to receive an optional display 50 electrically secured to and in communication with the PCB 38. The PCB 38 includes suitable circuitry for displaying mode selections, measurements, test data, and other electrical properties on the display 50. One of the pushbuttons 54 may also be used to “hold” the display in its current reading when the first and second probes 20 and 22 are disengaged from the voltage source. In this manner, if the display 50 is not visible when the measurement is being taken (due to low lighting conditions, a cramped space, etc.), the user can read the measurement on the display 50 after the measurement has been taken.

The indicator assembly 34 further includes a plurality of transparent or translucent panels 62 formed or received within the base 42 above the pushbuttons 54. The panels 62 are arranged on the base 42 such that they cover a light source secured on the PCB 38 when the indicator assembly 34 is mated with the PCB 38. Each light source is preferably a light emitting diode (LED) 64 in electrical communication with the PCB circuitry and the probe assembly 18. Each LED 64 is adapted to selectively illuminate when an electrical circuit is completed with the first and second probes 20 and 22, thereby selectively illuminating the panels 62 and activating the panels 62 into an “on” state.

Each of the panels 62 includes a graphically represented visible indicator 66 corresponding to a measured property of an electrical circuit. The indicator 66 may be graphically represented on the panels 62 in any suitable manner, such as engraving, by applying paint, ink, stain, etc., to the exterior or interior of the panels 62 before or after the panels 62 are formed or during the forming process. The indicators 66 may either be defined by an absence of paint, ink, stain, etc., on a dark background (as shown in the FIGURES) or by the application of the paint, ink, stain, etc., on the panel 62 to define the indicator 66 itself. The indicators 66 are selectively illuminated when the LEDs are illuminated behind the panels 62.

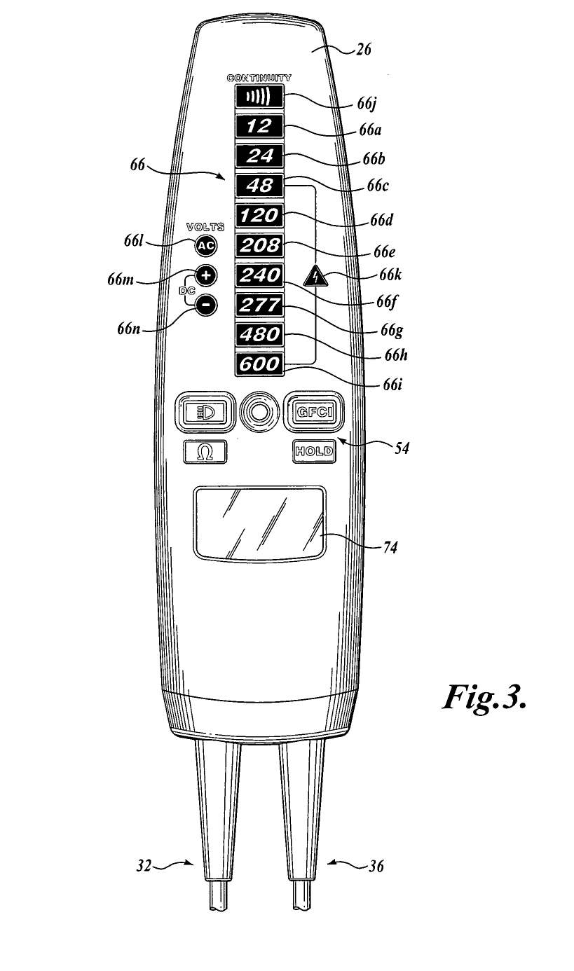

Although the indicator assembly 34 may include any suitable arrangement of panels 62 and indicators 66 for representing the measured properties of an electrical circuit, the indicator assembly 34 preferably includes panels 62a-62i having numerical indicators 66a-66i, respectively, as shown in FIGS. 2 and 3. The numerical indicators 66a-66i correspond to the magnitude of typical voltage measurements of an electrical circuit, such as, but not limited to 12V, 24V, 48V, 120V, 208V, 240V, 277V, 480V, and 600V, respectively. It should be appreciated that the indicators 66a-66i may instead correspond to any other voltage measurements. For instance, that would make the voltmeter 10 suitable for use in other countries. The panels 62a-62i are arranged in a substantially vertical manner with the numerical indicators 66a-66i in ascending order so as to represent a increasing scale of voltage.

Referring to FIGS. 2 and 3, the indicator assembly 34 includes a panel 62j positioned above panels 62a-62i and having an indicator 66j that represents the continuity of the electrical circuit being tested. The indicator 66j may be any suitable symbol for representing the continuity of an electrical circuit, such as a symbol depicting a signal. The indicator assembly 34 further includes a panel 62k positioned near panels 62c-62i and having an indicator 66k that communicates a warning of high voltage. The indicator 66k may be any suitable symbol for representing high voltage, such as a lighting bolt. Moreover, the panel 62k is preferably triangular-shaped to further communicate a warning.

The indicator assembly 34 also includes panels 62l, 62m, and 62n having indicators 66l, 66m, and 66n, respectively for communicating whether the electrical circuit is alternating current (AC) or direct current (DC) as well as the voltage polarity of a DC electrical circuit. For instance, indicator 66l may include the letters “AC” to represent an alternating current circuit. Indicator 66m may include a symbol representing a positive polarity DC circuit, such as a plus sign (“+”), and indicator 66n may include a symbol representing a negative polarity DC circuit, such as a negative sign (“−”).

Referring to FIGS. 1 and 2, the voltmeter 10 is assembled by electrically securing the first and second leads 32 and 36 to the circuitry of the PCB 38 in any suitable manner (not shown), and thereafter mating the indicator assembly 34 to the PCB 38. The display 50 is received within the bottom opening 46 of the indicator assembly 34 and the pushbuttons 54 are adapted to engage electrical contacts 58 on the PCB 38. Further, one of each of the plurality of LEDS 64 is positioned behind one of each of the panels 62 such that the LEDs may individually illuminate the panels 62.

The indicator assembly 34 and PCB 38 are thereafter enclosed between the front and rear housing portions 26 and 30. The front housing portion 26 includes a plurality of openings 70 corresponding to the shape, size, and location of the pushbuttons 54 and panels 62 on the base 42. As such, the indicator assembly 34 is mated with the front housing portion 26 such that the pushbuttons 54 and panels 62 are received within the openings 70. The pushbuttons 54 protrude at least partially through the front housing portion 26 to allow a user to make selections when using the voltmeter 10 by depressing the pushbuttons 54.

The panels 62 also protrude at least partially through the front housing portion 26; however, the panels 62 may instead be flush with the exterior surface of the front housing portion 26 when received therein. It should also be appreciated that the panels 62 may instead be formed within the front housing portion 26 rather than being formed separately on the base 42. The front housing portion 26 further includes a window 74 that is positioned in front of the display 50 when the indicator assembly 34 is mated with the front housing portion 26. It should be understood that the voltmeter 10 may instead be assembled in any other suitable manner.

Referring to FIGS. 1 and 3, one manner of using the voltmeter 10 to test an electrical circuit will now be described. The voltmeter 10 is shown testing an electrical outlet O having at least one socket S, such as a NEMA 5-15 electrical outlet. The socket S includes a neutral slot N and a live slot L. To measure the voltage of the outlet O, the first conductive tip 24 of the first probe 20 is inserted within the neutral slot N and the second conductive tip 28 of the second probe 22 is inserted within the live slot L. The first and second probes 20 and 22 form a closed circuit with the electrical outlet O.

When the voltmeter 10 forms a closed circuit with the outlet O, the LED 64 positioned behind panel 62j having the continuity indicator 66j is illuminated to indicate the circuit is closed. Moreover, the LED 64 positioned behind the panel 62 having the indicator 66 corresponding to the magnitude of the measured voltage is illuminated to indicate the measured voltage. For instance, if the outlet O has a voltage near 120V, then the LED 64 behind panel 62d and indicator 66d is illuminated to communicate to the user that about 120V is being measured. With the indicator 66d illuminated by the LED, the user can clearly see the voltage measurement in low lighting conditions.

To further indicate the magnitude of the voltage being measured, the panels 62 having an indicator 66 corresponding to a magnitude less than the measured voltage may also be illuminated by the LEDs 64. For example, if the measured voltage is near 120V, panels 62a, 62b, and 62c having indicators 66a, 66b, and 66c (with numbers “12,” “24,” and “48,” respectively) are illuminated in addition to panel 62d having the indicator 66d of “120.” With the indicators 66 arranged in ascending order and the panels illuminated as such, the panels 62 act as a scale to indicate the magnitude of the measured voltage.

If the magnitude of the voltage is greater than a predetermined value, such as 48V, the LED 64 positioned behind panel 62k having the voltage warning indicator 66k is illuminated to indicate a high voltage. Moreover, at least one of the panels 62l, m, or n having the indicators 66l, m, or n (with the “AC”, “+”, and “−” indicators, respectively) is illuminated to represent the voltage polarity. It should be appreciated that additional panels and indicators may be used to represent other measured electrical properties of an electrical circuit.

While illustrative embodiments have been illustrated and described, it will be appreciated that various changes can be made therein without departing from the spirit and scope of the present disclosure. For instance, the voltmeter 10 may additionally include tactile or audible indicators that correspond to the magnitude of a measured voltage. More specifically, the voltage tester may include a controller that produces a sound or vibration when a closed circuit is formed. As such, the foregoing description should be seen as illustrative and not limiting the scope of the claimed subject matter.

The embodiments of the present disclosure in which an exclusive property or privilege is claimed are defined as follows:

1. An instrument for testing an electrical circuit, the instrument comprising:
(a) a housing;
(b) a printed circuit board disposed within the housing;
(c) at least one probe in electrical communication with the printed circuit board; and
(d) a plurality of panels disposed within the housing, each one of the plurality of panels having an indicator, each of the plurality of panels capable of being activated into an on state in response to an electrical measurement such that when at least one of the plurality of panels is activated the indicator on that panel substantially corresponds to a magnitude of the electrical measurement.

2. The instrument of claim 1, wherein each one of the indicators is different at least in part from the remaining indicators such that none of the indicators are identical.

3. The instrument of claim 1, further comprising a light source disposed beneath each one of the plurality of panels.

4. The instrument of claim 3, wherein the light source beneath the indicator substantially corresponding the magnitude of the electrical measurement is illuminated when the instrument is in communication with electrical circuit.

5. The instrument of claim 1, wherein at least one of the plurality of indicators when activated is illuminated to indicate the magnitude of the electrical measurement.

6. The instrument of claim 1, wherein the panels having indicators corresponding to a magnitude less than the electrical measurement are activated in response to the electrical measurement.

7. The instrument of claim 6, wherein the panels are arranged such that the indicators are in ascending order.

8. The instrument of claim 1, wherein at least a portion of the indicators are numbers that substantially correspond to the magnitude of the electrical measurement.

9. The instrument of claim 1, wherein at least one of the plurality of panels is a warning indicator that is activated into an on state when the magnitude of the electrical measurement exceeds a predetermined value.

10. The instrument of claim 1, further comprising a display disposed within the housing, the display indicating properties of the electrical circuit.

11. The instrument of claim 1, further comprising a panel having an indicator corresponding to the polarity of an electrical circuit.

12. An instrument for testing an electrical circuit, the instrument having a housing, a printed circuit board disposed within the housing, at least one probe in electrical communication with the printed circuit board, and an indicator assembly, the indicator assembly comprising:
(a) a plurality of panels disposed within the housing, each panel having a visible indicator; and
(b) a light source disposed beneath each one of the plurality of panels, wherein the light source beneath the indicator substantially corresponding to the magnitude of an electrical measurement is illuminated when the instrument is in communication with an electrical circuit.

13. The indicator assembly of claim 12, wherein each one of the visible indicators is different at least in part from the remaining visible indicators such that none of the visible indicators are identical.

14. The indicator assembly of claim 12, wherein the light sources positioned beneath the indicators corresponding to a magnitude less than the electrical measurement are illuminated in response to the electrical measurement.

15. The indicator assembly of claim 14, wherein the panels are arranged such that the indicators are in ascending order.

16. The indicator assembly of claim 12, wherein at least a portion of the visible indicators are numbers that substantially correspond to the magnitude of an electrical measurement.

17. The indicator assembly of claim 12, wherein at least one of the plurality of panels is a warning indicator, and wherein the light source positioned beneath the warning indicator is illuminated when the magnitude of the electrical measurement exceeds a predetermined value.

18. The instrument of claim 12, further comprising a panel having an indicator corresponding to the polarity of an electrical circuit.
